(19) United States
(12) Patent Application Publication
(10) Pub. No.: US 2007/0296511 A1
(43) Pub. Date: Dec. 27, 2007

(54) DIGITAL ADJUSTMENT OF AN OSCILLATOR

(75) Inventors: Christophe Holuigue, Munchen (DE); Stephan Mechnig, Munchen (DE)

Correspondence Address: PEARNE & GORDON LLP, 1801 EAST 9TH STREET, SUITE 1200, CLEVELAND, OH, 44114-3108, US

(73) Assignee: NATIONAL SEMICONDUCTOR GERMANY AG, Unterhaching (DE)

(21) Appl. No.: 11/761,668

(22) Filed: Jun. 12, 2007

(30) Foreign Application Priority Data
Jun. 13, 2006 (DE) 10 2006 027 419.9

(51) Int. Cl. H03L 7/00

(52) U.S. Cl. 331/16

(57) ABSTRACT

The invention concerns the adjustment of an oscillation frequency of an oscillator, in particular the digital coarse adjustment of a PLL oscillator by means of a circuit arrangement comprising at least one pair of capacitors (C, C′), of which first terminals are connected with the oscillator, and second terminals can selectively be connected by means of a switching arrangement with a first reference potential (vss), in order to incorporate the capacitor pair (C, C′) into an oscillating circuit of the oscillator, wherein the circuit arrangement comprises: first FETs (T1, T1′) for the respective connection of the second terminals with the first reference potential (vss), a second FET (T2) for the connection of the second terminals with each other, and third FETs (T3, T3′) for the respective connection of the second terminals with a second reference potential (vdd), which differs from the first reference potential (vss).

### BACKGROUND TO THE INVENTION/FIELD OF THE INVENTION

The present invention concerns the adjustment of an oscillation frequency of an oscillator. In particular the invention concerns a circuit arrangement for a frequency adjustment of this kind as well as the use of a circuit arrangement of this kind.

### DESCRIPTION OF PRIOR ART

It is of known art to alter or adjust the oscillation frequency of an oscillator comprising an electrical oscillating circuit by selectively introducing an electrical capacitance into the oscillating circuit. In the field of microelectronics the selective connection of such a capacitance can advantageously be accomplished by means of one or a plurality of field effect transistors, in what follows designated as “FET” or “FETs”.

When using FETs for the selective connection (and disconnection) of (as necessary additional) capacitance in an oscillating circuit the problem ensues in practice, in particular if a very small capacitance is being connected, that parasitic capacitances of a greater or lesser size are always present between the various terminals, including the substrate of an FET. While these parasitic capacitances can indeed be taken into account in the design of a circuit arrangement used for the adjustment of the oscillation frequency, they disadvantageously reduce the adjustment range achievable with regard to the capacitance and accordingly with regard to the oscillation frequency. This problem is all the more serious the larger the dimensions of the FET concerned (channel length and/or channel width). A large channel width of an FET used for the selective connection of a capacitance is however advantageous or necessary inasmuch as the “on-resistance” of the FET, i.e. the electrical resistance of the source-drain path (channel) in the switched-on state of the FET, is thereby smaller. If the channel of the switched-on FET lies in an oscillating circuit path containing the connected capacitance, then a smaller on-resistance is particularly advantageous for avoiding damping of the oscillating circuit (or a reduction of the quality of the oscillating circuit) associated with the connection of the capacitance.

### OUTLINE OF THE INVENTION

It is therefore an object of the present invention to remove the disadvantages cited above, and in particular to enable an adjustment of an oscillation frequency of an oscillator, by means of which a selective alteration of the oscillation frequency can be achieved in an efficient manner, and without significant damping of the oscillator.

According to the invention a circuit arrangement for the adjustment of an oscillation frequency of an oscillator is provided, comprising at least one pair of capacitors, of which first terminals are connected with the oscillator, and second terminals can selectively be connected with a first reference potential by means of a switching arrangement, in order to introduce the capacitor pair into an oscillating circuit of the oscillator, wherein the circuit arrangement comprises:
first FETs for the respective connection of the second terminals with the first reference potential,
a second FET for the connection of the second terminals with each other, and
third FETs for the respective connection of the second terminals with a second reference potential, which differs from the first reference potential.

In the circuit arrangement according to the invention a capacitor pair can be introduced into the oscillating circuit of the oscillator, in that the first FETs are switched on and the second capacitor terminals are thus connected with the first reference potential. In order here to reduce the electrical resistance of the path introduced the second FET is provided, by means of which at the same time the second capacitor terminals can be connected with each other. Finally the third FETs can advantageously be used to reduce considerably the parasitic capacitances still active in the switched-off state of the first FETs and the second FET, in particular e.g. to reduce the source-substrate capacitance and the drain-substrate capacitance of the second FET, in that via the third FETs the potentials prevailing at the second capacitor terminals and thus at the source and drain terminals of the second FET are “shifted” in a manner such that the parasitic capacitances are reduced.

To connect in the capacitor pair, and the capacitance that they represent, the first FETs and also the second FET are switched on (and the third FETs are switched off). Preferably these FETs are dimensioned and/or controlled, such that in each case these create a comparatively low resistance connection (between the second capacitor terminals and the first reference potential by means of the first FETs, and between the second capacitor terminals by means of the second FET).

To disconnect the capacitor pair, and the capacitance that they represent, the first FETs and also the second FET are switched off and the third FETs are switched on. Thus potentials prevailing at the second capacitor terminals are in a manner displaced, as a result of which parasitic capacitances are reduced. In order to “decouple” particularly effectively from the oscillating circuit the connections created in this state by means of the third FETs, in a particularly preferred form of embodiment provision is made that the connections of the second capacitor terminals with the second reference potential, formed by means of the third FETs, are of comparatively high resistance. The term “high resistance” should here in particular comprise the case in which the on-resistance of a third FET is larger by at least a factor 10, in particular 100, than the on-resistance of the corresponding first FET and/or the second FET. Alternatively or additionally it can also be provided that the on-resistance of a third FET is greater than 10² Ω, in particular is greater than 10³ Ω.

In one form of embodiment provision is made that the capacitor pair is formed from identically dimensioned capacitor. In particular in this case it is also preferred if the first FETs are identically dimensioned and/or the third FETs are identically dimensioned.

In a particularly simple form of embodiment in terms of circuitry provision is made that the first and second reference potentials are formed from supply potentials of a microelectronic integrated circuit arrangement (e.g. in CMOS technology), which contains the circuit arrangement used for the adjustment of the oscillation frequency and preferably at least some of the components forming the oscillator.

In one form of embodiment provision is made that the oscillating circuit contains at least one inductive element, which together with at least one capacitor forms a system that can oscillate.

In a preferred form of embodiment the circuit arrangement according to the invention serves to provide a coarse adjustment of an oscillator that can be fine adjusted in another manner, for example, for the coarse adjustment of a voltage controlled oscillator (VCO). In a voltage controlled oscillator the oscillating circuit can be formed e.g. from an inductive element (e.g. a microelectronic design of coil), which interacts with a voltage controlled capacitor (varactor). In a manner known per se such an oscillating circuit can be “undamped” by means of active feedback, e. g. by means of at least one component with negative resistance. The varactor can be used for the fine adjustment of an oscillation frequency, which by means of the circuit arrangement according to the invention is coarse adjusted by appropriately connecting in one or a plurality of capacitor pairs.

In one form of embodiment that is very advantageous for a particularly large range of adjustment provision is made for a plurality of capacitor pairs to each of which a switching arrangement of the kind described is assigned. This plurality of capacitor pairs with a switching arrangement assigned in each case, can in particular be arranged in parallel with one another, wherein the first capacitor terminals are in each case connected with the same circuit nodes of the oscillator. These circuit nodes can e.g. take the form of terminals of the inductive element.

In one form of embodiment provision is made that a digital control signal can be applied to gate terminals of the first FETs and/or the third FETs. The circuit arrangement can thus advantageously be used for digital adjustment of the oscillation frequency. The capacitance values formed in each case by the individual capacitor pairs can here be identical, or can also differ from one another. In the latter case the capacitance values, or the oscillation frequencies that can be achieved by connecting in these capacitances, can be controlled e.g. in accordance with a binary code.

For the control of the first, second and third FETs with an appropriate FET design (in particular conduction type) a single digital control signal can be used to connect or disconnect a capacitor pair. It is also possible to use such a digital control signal for some of the FETs as a control signal (at the gate terminal), while an inverted version of this control signal is used for the control of other FETs. In an advantageous further development of the invention provision is made that a fixed control potential is applied to at least the gate terminal of the second FET, which can take the form e.g. of a supply potential of the circuit arrangement and/or of the oscillator. The switching on and off of the second FET is based in this case not on an alteration of the gate potential, but rather an alternation of the potentials, which is equally suitable for this purpose, prevailing at the source and drain terminals of the second FET, which alteration is brought about by the switching of the first and third FETs.

As has already been mentioned above, in accordance with an advantageous form of embodiment provision is made that the third FETs in the switched-on state provide a high resistance connection of the second terminals with the second reference potential. The on-resistance of a third FET that here ensues is preferably smaller than the off-resistance of this FET by at least a factor 10³.

The above-mentioned high resistance connection, created by means of a third FET in its switched-on state, can in a simple manner be ensured by means of a channel length of sufficiently large dimensions, in what follows also designated as “L”, or by a small channel width, in what follows also designated as “W”. In particular in this case, however, the problem can arise that the switching on of the third FET takes place comparatively slowly. This prevents a rapid adjustment of the oscillator frequency, or delays the reduction of the parasitic capacitances provided according to the invention. To remove this problem in accordance with a further development of the invention provision is made that the switch arrangement comprises a further fourth FET in parallel to each of the third FETs. With a brief switching-on of the fourth FET during the switching-on of the related third FET the “switching-on time period” of the third FET can to a certain extent be bridged by the fourth FET that is connected in parallel. In particular this is then very effective if the W/L ratio of the fourth FET is larger than the W/L ratio of the third FET arranged in parallel with the former (e.g. larger by at least a factor 2). The brief switching-on of the fourth FETs during the switching-on of the third FETs can be accomplished by means of an appropriately designed control circuit, into which is/are inputted the one or more control signals for the switching of the first, second and third FETS, and which on the basis of this signal or signals generates a control signal for the control of the fourth FETs and applies it to the gate terminals of the fourth FETs. Such a control circuit can for example have a logic array device and a delay element, which defines the switching-on duration of the fourth FETs.

A preferred use of the circuit arrangement according to the invention is for the digital coarse adjustment of a voltage controlled oscillator arranged in a phase locked loop.

A phase locked loop, also designated as a “PLL”, in very general terms serves the purpose of synchronising a controllable oscillator, which generates an output signal with an output frequency, with an input signal with an input frequency, by means of feedback. For this purpose the PLL comprises a phase detector or phase comparator, at whose input the PLL input signal and the PLL output signal are present. A signal representing the phase difference between these two signals is mainly used to control the oscillator via an active or passive, digital or analog filter (“loop filter”).

The areas of application for PLL circuits are many and varied. For example PLLs can be used for clock signal recovery from digital signal sequences, or for FM demodulation. In communication standards such as “SONET” or “SDH” clock generation circuits are required to generate clock signals during the transmission and receipt of data. In a circuit of this kind a PLL circuit can generate, e.g. from an input clock signal inputted as a reference, one or a plurality of output clock signals for use in a communication system. Here the synchronisation of the PLL output signal with an input clock signal does not necessarily mean that the frequencies of these two signals are identical. Rather in a manner known per se a more or less arbitrary frequency relationship can be implemented by an arrangement of frequency dividers at the input and/or at the output and/or in the feedback path of the PLL circuit.

The use of the circuit arrangement according to the invention in a PLL oscillating circuit for clock extraction or recovery is very advantageous inasmuch as a large PLL capture range can thus be achieved with, at the same time, a small phase error (in particular so-called “jitter”) in the PLL output clock signal. In this connection the following is to be considered: A large capture range requires in very general terms a more or less rapid and large adjustability of the oscillation frequency, as could be implemented e.g. by a varactor of relatively large dimensions in the oscillating circuit of the PLL oscillator. However, when using a varactor that can be adjusted over a wide range disturbances such as noise in the oscillator part can be converted more or less efficiently into phase errors as phase noise in the PLL output signal, and so a varactor with large dimensions has a tendency to deteriorate the quality of the PLL output signal. This problem can be overcome by means of the invention in that in the PLL a coarse adjustment designed according to the invention is combined in a manner known per se with a fine adjustment implemented in a varactor to achieve a large PLL capture range with, at the same time, a small phase error. In order to achieve here a high quality factor for the connected capacitors or capacitances, favourable for the achievement of a small phase error, switching transistors that have channel widths of comparatively large dimensions can be used directly, since according to the invention the parasitic capacitances that thus have a tendency to increase in size are reduced by the configuration according to the invention. The result is the creation of a capacitor arrangement in which the parasitic capacitances are minimised, without any significant impairment of the quality factor of the oscillating circuit (e.g. “LC tank”), combined with a rapid switching time.

### BRIEF DESCRIPTION OF THE DRAWINGS

In what follows the invention is further described with the aid of examples of embodiment with reference to the accompanying drawings. In the figures:

FIG. 1 shows a block diagram of a phase locked loop (PLL), comprising a voltage controlled oscillator (VCO) with coarse and fine adjustment of its oscillation frequency,

FIG. 2 shows a circuit diagram to illustrate the coarse adjustment of the oscillator,

FIG. 3 shows a circuit diagram to illustrate a coarse adjustment that has been improved relative to the embodiment of FIG. 2,

FIG. 4 shows a circuit diagram to illustrate a coarse adjustment according to a first form of embodiment of the invention,

FIG. 5 shows a circuit diagram corresponding to FIG. 4 to illustrate in detail the manner of functioning of the first form of embodiment, and

FIG. 6 shows a circuit diagram to illustrate a coarse adjustment according to a second form of embodiment of the invention.

### DESCRIPTION OF THE PREFERRED EMBODIMENT(S)

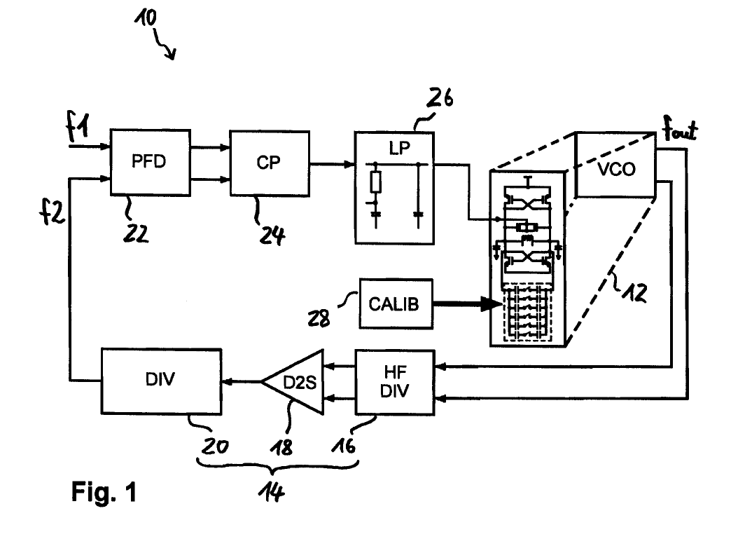

FIG. 1 shows a phase lock loop 10, in what follows designated as PLL 10, with a structure known per se. Such a PLL represents a preferred application environment for the circuit arrangement according to the invention described further below for the adjustment of an oscillation frequency.

The PLL 10 comprises a voltage controlled oscillator (VCO) 12 for the generation of a PLL output signal with a frequency fout, which is used for parts of a circuit, not represented in FIG. 1, of a “mixed signal” circuit arrangement, which also contains the components represented in FIG. 1.

The output signal of the VCO 12 is fed via a feedback path 14 consisting of a first frequency divider 16, a converter element 18 and a second divider 20 to an input of a phase detector or phase comparator 22 as a feedback signal with a frequency f2. An input clock signal (PLL input signal) is applied to another input of the phase detector 22; this signal has a frequency f1.

The fed-back frequency f2 corresponds to a fraction of the output frequency fout, which is defined by the product of the dividing factors of the dividers 16, 20. The converter element 18 converts the differential output signal of the first divider 16 into a signal that is referred to a fixed reference potential (“single ended”) and is forwarded to the input of the second divider 20. Deviating from the example of embodiment represented, in a manner known per se, alternatively or in addition to the dividers represented 16, 20, dividers could also be used in the input region (for the signal f1) and/or in the output region (for the signal fout).

The phase detector 22 generates at its output a control signal for a controllable current source 24 (“charge pump”), which is representative of the phase difference detected between the signals f1 and f2.

The current source 24, thus controlled as a function of the phase difference between f1 and f2, generates a current signal that is fed to a filter 26 (“loop filter”) with an integration characteristic. By means of the signal fed via the filter 26 a fine adjustment of the VCO 12 is undertaken with regard to its oscillation frequency fout, so that the output frequency fout is synchronised with the input frequency f1, i.e. these two frequencies are linked together by a prescribed frequency ratio.

For the coarse adjustment of the oscillation frequency of the VCO 12 provision is made for a digital adjustment device 28, which is also connected to the VCO 12 and serves to switch on and off in a desired manner the switching elements symbolised in FIG. 1, in order thus to incorporate in each case one of a plurality of capacitor pairs into an oscillating circuit of the VCO 12, or to remove the condenser pair from this oscillating circuit.

The oscillator 12 comprises, as represented in FIG. 1, an inductive element, which, with a capacitor arrangement and the capacitor pairs that can be selectively connected, forms an oscillating circuit whose resonant frequency essentially is a function of the value of the total capacitance currently connected (coarse adjustment by means of the device 28). First terminals of the capacitor that can be switched on are here in each case connected with the two terminals of the inductive element, whereas the second capacitor terminals of each capacitor pair can be connected with each other, as symbolised in FIG. 1. In parallel to the capacitor pairs that can selectively be connected the oscillating circuit comprises a varactor, which is controlled by the signal fed from the filter 26 (fine adjustment within the framework of PLL regulation). Finally provision is made for a transistor arrangement that in an active manner compensates for the electrical losses in the oscillating circuit and thus removes damping from the oscillating circuit. Although the topology of the VCO 12 that can be seen in FIG. 1 represents a preferred embodiment, this configuration also allows extensive modifications. The actual implementation of the oscillator 12 in terms of circuitry is of secondary significance within the framework of the invention.

The core of the invention concerns the art and manner in which the selectively provided capacitance values of the capacitor pairs are selectively connected into, or subsequently removed from, the oscillating circuit.

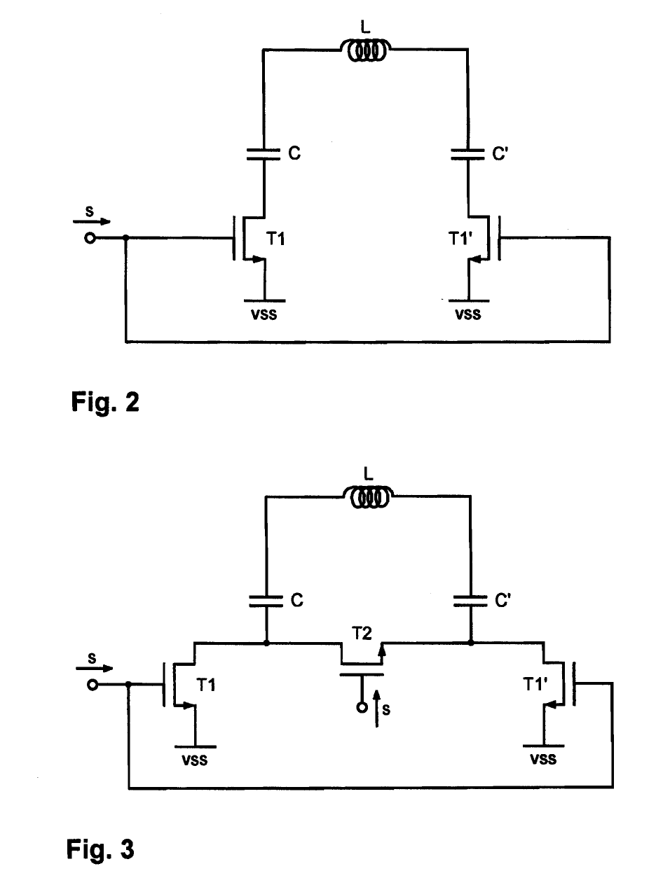

FIGS. 2 and 3 illustrate for the example of a single capacitor pair C, C′ a circuit arrangement for the adjustment of an oscillator based on internal company developments by the applicant, of which for the sake of simplicity in FIGS. 2 and 3 only one inductive element (coil) L is represented and which in total for example possesses the structure represented in FIG. 1.

In the embodiment according to FIG. 2 first terminals of the condensers C, C′ are connected with the two terminals of the inductive element L, and second terminals can selectively be connected by means of a switching arrangement with a reference potential vss, in order to incorporate the condenser pair C, C′ into the oscillating circuit of the oscillator concerned. The switching arrangement is formed from two first FETs T1, T1′, by means of which each of the second capacitor terminals can be connected with the reference potential vss. Here the control of the FETs T1, T1′, takes place via a digital control signal s, which is fed to the gate terminals of the FETs T1, T1′ (in the PLL of FIG. 1 such a control signal s can be generated from the digital adjustment device 28).

In the switched-on state of the FETs T1, T1′ the second capacitor terminals are connected via low resistance paths (conducting FETs) with the reference potential vss, which represents a supply potential of the overall system. In this switched-on state a series arrangement of the capacitors C and C′ is incorporated into the oscillating circuit, such that a particular oscillation frequency ensues.

By switching off the FETs T1, T1′ the capacitor pair C, C′ can subsequently be removed from the oscillating circuit, leading to a corresponding alteration of the oscillation frequency. In the switched-on state of the FETs two channel resistances are present in a path of the oscillating circuit, so that its quality factor is reduced to a greater or lesser extent. In order to maintain this impairment at a low level, the channel widths of the FETs T1, T1′ should be of comparatively large dimensions, so that their on-resistance is correspondingly small. This in turn tends to increase the parasitic capacitances (diffusion capacitances in the source and drain regions of T1 and T1′) present in the switched-off state of these transistors. This in turn reduces the adjustment range for the oscillation frequency.

In the following description of further examples of embodiment the same reference symbols are used for components acting in a similar manner, and essentially only differences from the respective previous embodiments are described.

A certain improvement of the circuit arrangement represented in FIG. 2 is achieved with a circuit arrangement according to FIG. 3.

FIG. 3 shows a circuit arrangement in which in addition a FET T2 is provided to connect the second capacitor terminals with each other. The second FET T2 is here controlled simultaneously with the first FETs T1, T1′ by means of the common digital control signal s. In the switched-on state of all FETs the resistive component of the switched-on oscillating circuit path is advantageously reduced. The problems associated with the parasitic capacitances in the switched-off state of the FETs T1, T1′, T2 nevertheless remain.

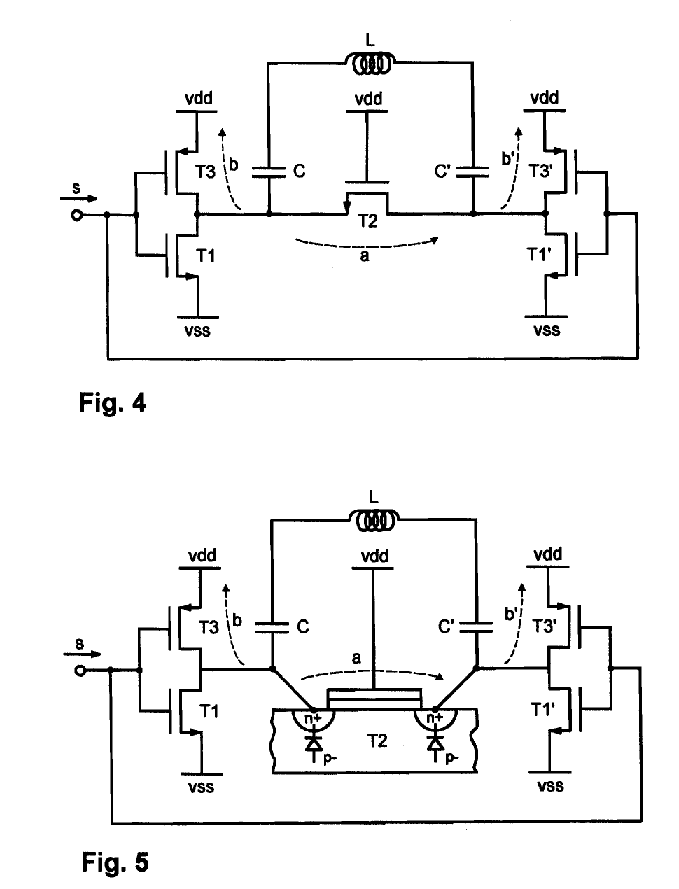

FIG. 4 illustrates a first example of embodiment of the invention.

In this circuit arrangement third FETs T3, T3′ are additionally provided, each of which is assigned to one of the first FETs T1, T1′ and is connected in series with these transistors such that in this manner the second capacitor terminals can be connected with a second reference potential vdd, which differs from the first reference potential vss and which in the example of embodiment represented represents, compared with vss, a positive second supply potential for the overall system.

The control signal s is applied to the control terminals (gate terminals) of these third FETs T3, T3′. A further modification of the circuit arrangement represented in FIG. 4 compared with the embodiment according to FIG. 3 consists in the fact that the control signal s is not applied to the gate terminal of the second FET T2, (which would be possible), but rather the gate terminal is connected to the second reference potential vdd.

The function of the circuit arrangement for the selective connection of the capacitor pair C, C′ is based on the simultaneous switching on or off of the first and second FETs T1, T1′, T2, as has already been described above. The third FETs are, however, operated in a complementary manner, in the sense that these are switched on if T1, T1′ and T2 are switched off, whereas the third FETs T3, T3′ are switched off if T1, T1′ and T2 are switched on. The third FETs T3, T3′ are dimensioned with regard to their channel length L and channel width W such that these in the switched-on state form “high resistance paths” b and b′ between the condensers C, C′ and vdd, and in the switched-off state form “very high resistance paths” b and b′.

In the switched-on state of T1, T1′, T2 (capacitor pair connected) T3, T3′ possess practically no influence on the arrangement.

If in contrast T1, T1′, T2 are switched off (capacitor pair disconnected from the oscillating circuit) then the (high resistance) connection between the second capacitor terminals and the second reference potential vdd leads to the fact that potentials prevailing at the second capacitor terminals and thus at the corresponding terminals of the transistors T1, T1′, T2 are “pulled” in the direction of the reference potential vdd, leading to a significant reduction in the undesired parasitic capacitances. In summary, in the connected state of the capacitor pair a low resistance path a ensues, and when the capacitor pair is disconnected two high resistance paths b, b′ ensue.

This advantageous action of the additional third FETs T3, T3′ is once again made clear in a detailed representation of the structure of T2 in FIG. 5. For the example of the FET T2 “pn-diodes” are symbolised in FIG. 5 as elements of an NMOS transistor design, on which diodes the parasitic capacitances are present as diffusion capacitances. The value of these parasitic capacitances at the source terminal and drain terminal of T2 is strongly dependent on the difference of the potentials between the source terminal and the substrate, and between the drain terminal and the substrate of T2. As a result of the high resistance paths created in the disconnected state of the capacitor pair C, C′ with the transistors T3, T3′ the potentials at the source terminal and drain terminal of T2 are increased by substantially the same amount, so that the values of the parasitic capacitances are drastically reduced (the substrate of T2 is connected with vss).

Since in the example of embodiment according to FIGS. 4 and 5 the third FETs T3, T3′ have a conduction type (PMOS) that differs from that of the first FETs T1, T1′ (NMOS), the digital control signal s can advantageously be used directly for the control of all transistors. Since with the connection and disconnection of the capacitor pair the potentials prevailing at the second capacitor terminals vary correspondingly strongly, the second FET T2 can be switched by means of this alteration in potential (gate terminal of T2 is permanently connected with vdd).

In summary a method is provided with the following steps for the adjustment of the oscillation frequency of an oscillator:
selective connection of second terminals of a pair of capacitors with a first reference potential vss by the switching-on of first FETs T1, T1′, and with each other by the switching-on of a second FET T2, wherein first terminals of the capacitors are connected with the oscillator, and
with the switching-off of T1, T1′, T2, connection of the second terminals with a second reference potential vdd by the switching-on of third FETs T3, T3′.

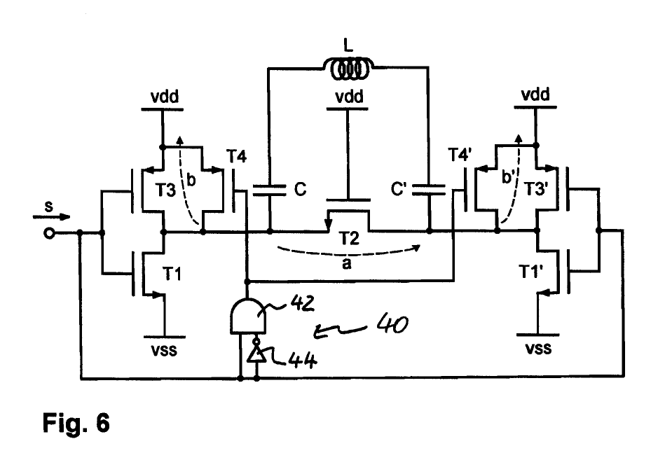

FIG. 6 shows a modified example of embodiment of the invention, in which compared with the example of embodiment according to FIGS. 4 and 5 further fourth FETs T4, T4′ are provided, each of which is arranged in parallel to one of the third FETs T3, T3′, and is controlled in a simultaneous manner by means of a control circuit 40. For this purpose an output terminal of the control circuit 40 is connected with the gate terminals of the FETs T4, T4′ designed as PMOS transistors.

With the switching-on of the third FETs T3, T3′, the control circuit 40 serves to switch on briefly also the fourth FETs T4, T4′. This ensures that the creation of the high resistance paths b, b′ is accelerated. The switching-on of T3 and T3′ by the control signal s actually takes place comparatively slowly, since these transistors are dimensioned to ensure a high resistance path. The FETs T4, T4′ serving as “boost” transistors overcome (bridge) to a certain extent the duration necessary for switching-on of T3, T3′. For this purpose it is appropriate if T4, T4′ are dimensioned such that these can be switched on rapidly, wherein these can (very briefly) also create a relatively low resistance path. In the dimensioning of T4, T4′ provision can e.g. be made that the channel width W is significantly larger than the channel length L. Independently of this it is preferred if the ratio between channel width W and channel length L for the fourth FETs is significantly larger than the corresponding ratio for the third FETs, in each case arranged in parallel to the former.

In the form of embodiment represented the control circuit 40 functions as follows: The control signal s is inputted to an input of an OR-gate 42. The control signal s is inputted to a second input of the OR-gate 42 via an inverting delay device 44. The signal s possesses the logical value “0” (low potential, e.g. vss), if the capacitor pair C, C′ are to be connected (T1, T1′ and T2 switched on with low resistance). The signal s possesses the logical value “1” (high potential, e.g. vdd), if the capacitor pair C, C′ are to be inactive (T1, T1′ and T2 switched off and T3, T3′ switched on with high resistance).

In this case a brief change of signal state from 1 to 0 is generated at the output of the OR-gate 42 exactly at the point in time when the control signal s changes from the value 1 to the value 0, i.e. when the high resistance path is to be created via T3, T3′.

The transistors T4, T4′ are accordingly switched on briefly, wherein the switching-on duration corresponds to the delay of the delay element 44. This brief switching-on of T4, T4′ helps to “pull towards vdd” the potentials prevailing at the second capacitor terminals.

Needless to say the circuit arrangements represented on the one hand in FIGS. 4 and 5 and on the other hand in FIG. 6 can also be provided in multiple form in parallel with one another in an oscillator (as is symbolised e.g. in FIG. 1).

1. A circuit arrangement for the adjustment of an oscillation frequency (fout) of an oscillator (12), comprising at least one pair of capacitors (C, C′), of which first terminals are connected with the oscillator (12), and second terminals can selectively be connected by means of a switching arrangement with a first reference potential (vss), in order to incorporate the capacitor pair (C, C′) into an oscillating circuit of the oscillator (12), wherein the circuit arrangement comprises:
first FETs (T1, T1′) for the respective connection of the second terminals with the first reference potential (vss),
a second FET (T2) for the connection of the second terminals with each other, and
third FETs (T3, T3′) for the respective connection of the second terminals with a second reference potential (vdd), which differs from the first reference potential (vss).

2. The circuit arrangement according to claim 1, for the coarse adjustment of a voltage controlled oscillator (12).

3. The circuit arrangement according to claim 1, wherein
a plurality of capacitor pairs (C, C′) is provided, to each of which a switching arrangement is assigned.

4. The circuit arrangement according to claim 1, wherein
a digital control signal (s) can be applied to gate terminals of the first FETs (T1, T1′) and/or the third FETs (T3, T3′).

5. The circuit arrangement according to claim 1, wherein
a fixed control potential (vdd) is applied to the gate terminal of the second FET (T2).

6. The circuit arrangement according to claim 1, wherein
the third FETs (T3, T3′) in the switched-on state provide a high resistance connection of the second terminals with the second reference potential (vdd).

7. The circuit arrangement according to claim 1, wherein
the switching arrangement comprises a further fourth FET (T4, T4′) in parallel to each of the third FETs (T3, T3′).

8. The circuit arrangement according to claim 7, wherein
the W/L ratio of the fourth FET (T4, T4′) is greater than the W/L ratio of the third FET (T3, T3′) arranged in parallel with the former.

9. The circuit arrangement according to claim 8, comprising a control circuit 40, which is designed to switch on briefly the fourth FETs (T4, T4′) when the third FETs (T3, T3′) are switched on.

10. A use of a circuit arrangement according to claim 1, for the digital coarse adjustment of a voltage controlled oscillator (12) arranged in a phase locked loop (10).
